(19) United States
(12) Patent Application Publication
(10) Pub. No.: US 2023/0411327 A1
(43) Pub. Date: Dec. 21, 2023

(54) SEMICONDUCTOR DEVICE AND SEMICONDUCTOR STORAGE DEVICE

(71) Applicant: Kioxia Corporation, Tokyo (JP)

(72) Inventor: Masayoshi TAGAMI, Kuwana Mie (JP)

(21) Appl. No.: 18/176,474

(22) Filed: Feb. 28, 2023

(30) Foreign Application Priority Data
Jun. 21, 2022 (JP) 2022-099892

(51) Int. Cl. H01L 23/00; H10B 80/00; H01L 25/16

(52) U.S. Cl. CPC H01L 24/08; H10B 80/00; H01L 24/09; H01L 24/05; H01L 25/16; H01L 2224/05005; H01L 2224/05014; H01L 2224/05018; H01L 2224/05073; H01L 2224/05573; H01L 2224/05541; H01L 2224/05558; H01L 2224/0903; H01L 2224/09051; H01L 2224/0801; H01L 2224/08055; H01L 2224/08057; H01L 2224/08145; H01L 2924/1438; H01L 2924/1431; H01L 2224/05647; H01L 2224/05554

(57) ABSTRACT

According to one embodiment, a semiconductor device includes a first chip with a first electrode and a second electrode and a second chip with a third electrode and a fourth electrode. The first and second chips are bonded to each other with the first electrode contacting the third electrode and the second electrode contacting the fourth electrode. A thickness of the first electrode in a first direction perpendicular to a bonding interface between the first chip and the second chip is less than a thickness of the second electrode in the first direction. A planar area of the first electrode at the bonding interface is greater than a planar area of the second electrode at the bonding interface.

### CROSS-REFERENCE TO RELATED APPLICATION(S)

This application is based upon and claims the benefit of priority from Japanese Patent Application No. 2022-099892, filed Jun. 21, 2022, the entire contents of which are incorporated herein by reference.

### FIELD

Embodiments described herein relate generally to a semiconductor device and a semiconductor storage device.

### BACKGROUND

There is a technique of bonding two chips in which electronic circuits. The chips have electrodes and insulating layers provided on the front surfaces thereof, and the electrodes of the respective chips can be bonded to one another.

### BRIEF DESCRIPTION OF THE DRAWINGS

FIG. 1 is a schematic cross-sectional view of a semiconductor device according to a first embodiment.

FIG. 2 is an enlarged schematic cross-sectional view illustrating a portion of the semiconductor device according to the first embodiment.

FIG. 3 is a plan view of a bonding interface of a semiconductor device according to a first embodiment.

FIG. 4 is an explanatory diagram illustrating aspects of a method of manufacturing a semiconductor device according to a first embodiment.

FIG. 5 is an enlarged schematic cross-sectional view illustrating a portion of a semiconductor device according to a comparative example.

FIG. 6 is a plan view illustrating a bonding interface of a semiconductor device according to the comparative example.

FIG. 7 is an explanatory diagram illustrating a problem of a semiconductor device according to the comparative example.

FIG. 8 is an explanatory diagram illustrating an action and an effect of a semiconductor device according to a first embodiment.

FIG. 9 is an enlarged schematic cross-sectional view illustrating a portion of a semiconductor device according to a second embodiment.

FIG. 10 is a schematic plan view illustrating a semiconductor device according to a second embodiment.

FIG. 11 is an enlarged schematic cross-sectional view illustrating a portion of a semiconductor device according to a modification of a second embodiment.

FIG. 12 is an enlarged schematic cross-sectional view illustrating a portion of a semiconductor device according to a third embodiment.

FIG. 13 is a schematic plan view illustrating a semiconductor device according to a third embodiment.

FIG. 14 is a schematic cross-sectional view illustrating a semiconductor storage device according to a fourth embodiment.

FIG. 15 is a circuit diagram illustrating a first memory cell array of a semiconductor storage device according to a fourth embodiment.

FIGS. 16A and 16B are schematic cross-sectional views of a first memory cell array of a semiconductor storage device according to a fourth embodiment.

FIG. 17 is an enlarged schematic cross-sectional view illustrating a portion of a semiconductor storage device according to a fourth embodiment.

FIG. 18 is a schematic plan view illustrating a semiconductor storage device according to a fourth embodiment.

### DETAILED DESCRIPTION

In general, according to one embodiment, a semiconductor device includes a first chip with a first electrode and a second electrode and a second chip with a third electrode and a fourth electrode. The second chip is bonded to the first chip with the third electrode in contact with the first electrode and the fourth electrode in contact with the second electrode. A first thickness of the first electrode in a first direction perpendicular to a bonding interface between the first chip and the second chip is less than a second thickness of the second electrode in the first direction. A first planar area of the first electrode at the bonding interface is greater than a second planar area of the second electrode at the bonding interface.

Certain example embodiments of the present disclosure are described below with reference to the drawings. In the following description, the same or substantial similar components, members, or aspects are denoted by the same reference symbols, and description of already described components, members, or aspects may be omitted from subsequent description of example embodiments.

Also, in this specification, terms such as “upper,” “above,” “lower,” and “below” and the like may be used for convenience. Such terms reference relative positional relationships as depicted in the drawings or the like, but do not necessarily define positional relationships with respect to gravity in actual embodiments.

The qualitative analysis and quantitative analysis of chemical compositions of materials and components constituting a semiconductor device may be performed by, for example, Secondary Ion Mass Spectrometry (SIMS) or Energy Dispersive X-ray Spectroscopy (EDX). In addition, a transmission electron microscope (TEM) or a scanning electron microscope (SEM) may be used for measuring a thickness or other dimension of a component of the semiconductor device or a distance between different components.

### First Embodiment

A semiconductor device according to a first embodiment includes a first chip that has a first electrode and a second electrode and a second chip that has a third electrode that contacts the first electrode and a fourth electrode that contacts the second electrode. The second chip is bonded to the first chip. A thickness of the first electrode in a first direction perpendicular to a bonding interface between the first chip and the second chip is less than a thickness of the second electrode in the first direction. The planar area of the first electrode at a bonding interface is larger than the planar area of the second electrode at the bonding interface.

The semiconductor device according to the first embodiment is a logic IC 100.

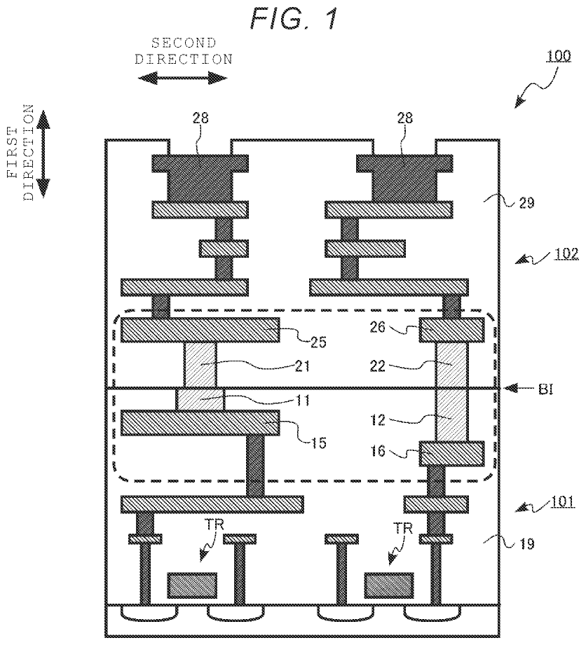

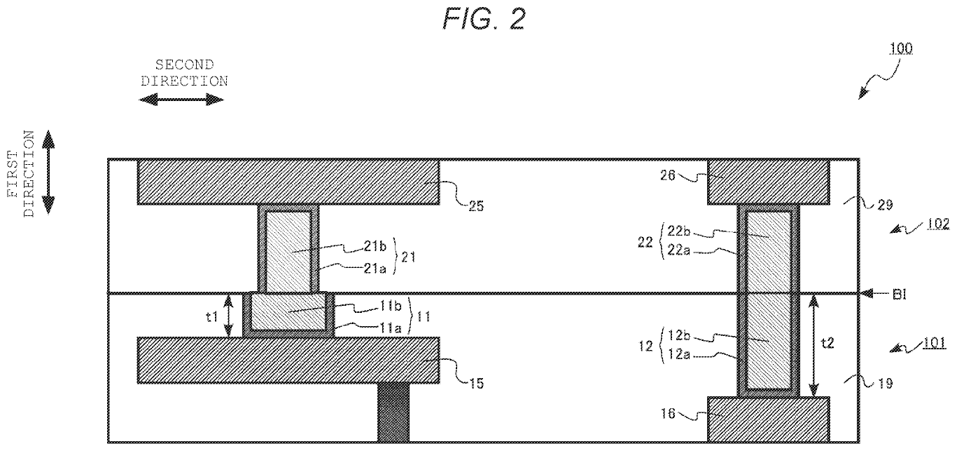

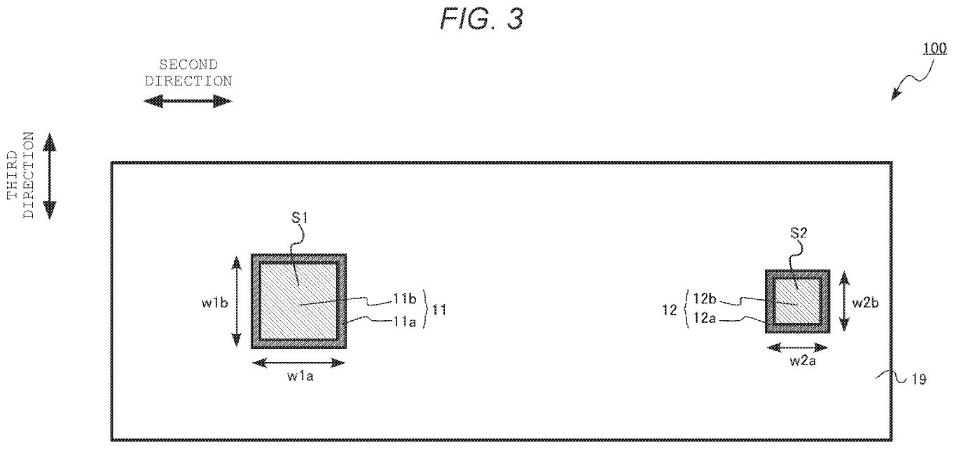

FIG. 1 is a schematic cross-sectional view of the semiconductor device according to the first embodiment. FIG. 2 is an enlarged schematic cross-sectional view of a portion of the semiconductor device according to the first embodiment. FIG. 2 is a cross-sectional view illustrating a region surrounded by a dotted line in FIG. 1. FIG. 3 is a schematic plan view illustrating the semiconductor device according to the first embodiment. FIG. 3 is a plan view of the bonding interface of the semiconductor device according to the first embodiment.

The logic IC 100 includes a transistor chip 101 and a wiring chip 102 in this example. The transistor chip 101 is an example of a first chip. The wiring chip 102 is an example of a second chip.

The transistor chip 101 includes a plurality of transistors TR, a metal pad 11, a metal pad 12, a first conductive layer 15, a second conductive layer 16, and a first interlayer insulating layer 19. The metal pad 11 is an example of a first electrode. The metal pad 12 is an example of a second electrode.

The wiring chip 102 includes a metal pad 21, a metal pad 22, a third conductive layer 25, a fourth conductive layer 26, an external connection electrode pad 28, and a second interlayer insulating layer 29. The metal pad 21 is an example of a third electrode. The metal pad 22 is an example of a fourth electrode.

The transistor chip 101 and the wiring chip 102 are bonded to each other at a bonding interface BI. The transistor chip 101 and the wiring chip 102 are bonded to each other by using a hybrid bonding technology that collectively bonds an electrode and an insulating layer.

In the following, a direction orthogonal to the bonding interface BI between the transistor chip 101 and the wiring chip 102 is referred to as the first direction. A direction perpendicular to the first direction is referred to as the second direction. A direction perpendicular to the first and second directions is referred to as the third direction.

Electronic circuits including the transistors TR are provided in the transistor chip 101. Examples of the transistors TR include a metal oxide field effect transistor (MOSFET) having a channel formed in a silicon layer.

The metal pad 11 is surrounded by the first interlayer insulating layer 19. The metal pad 11 is in contact with the first conductive layer 15. The metal pad 11 is electrically connected to the first conductive layer 15.

As illustrated in FIGS. 2 and 3, the metal pad 11 includes a barrier metal film 11a and a metal unit 11b. The barrier metal film 11a is provided between the metal unit 11b and the first conductive layer 15 and between the metal unit 11b and the first interlayer insulating layer 19.

The metal pad 11 comprises a metal. The metal unit 11b of the metal pad 11 comprises, for example, copper (Cu). The metal unit 11b of the metal pad 11 is, for example, copper (Cu).

The barrier metal film 11a of the metal pad 11 comprises, for example, a metal or metal nitride. In some examples, barrier metal film 11a may include at least one metal element selected from the group consisting of titanium (Ti), tantalum (Ta), manganese (Mn), and cobalt (Co). The barrier metal film 11a is, for example, a titanium film, a titanium nitride film, or a tantalum nitride film.

The metal pad 12 is provided in the second direction from the metal pad 11. The metal pad 12 is surrounded by the first interlayer insulating layer 19. The metal pad 12 is in contact with the second conductive layer 16. The metal pad 12 is electrically connected to the second conductive layer 16.

As illustrated in FIGS. 2 and 3, the metal pad 12 includes a barrier metal film 12a and a metal unit 12b. The barrier metal film 12a is provided between the metal unit 12b and the second conductive layer 16 and between the metal unit 12b and the first interlayer insulating layer 19.

The metal pad 12 comprises a metal. The metal unit 12b of the metal pad 12 comprises, for example, copper (Cu). The metal unit 12b of the metal pad 12 is, for example, copper (Cu).

The barrier metal film 12a of the metal pad 12 comprises, for example, a metal or metal nitride. In some examples, barrier metal film 12a may comprise at least one metal element selected from the group consisting of titanium (Ti), tantalum (Ta), manganese (Mn), and cobalt (Co). The barrier metal film 12a is, for example, a titanium film, a titanium nitride film, or a tantalum nitride film.

The metal pad 12 can be the same material as the metal pad 11.

The first conductive layer 15 can be electrically connected to the source or the drain of the transistor TR.

The first conductive layer 15 is provided in the first direction from the metal pad 11. The first conductive layer 15 is a conductor material. The first conductive layer 15 is, for example, a metal. The first conductive layer 15 comprises, for example, copper (Cu) or tungsten (W).

The second conductive layer 16 is electrically connected to the source or the drain of the transistor TR.

The second conductive layer 16 can be provided in the first direction from the metal pad 12. The second conductive layer 16 is a conductor material. The second conductive layer 16 is, for example, a metal. The second conductive layer 16 comprises, for example, copper (Cu) or tungsten (W).

The first interlayer insulating layer 19 has a function of providing electrical insulation in the transistor chip 101. The first interlayer insulating layer 19 is an insulator material. The first interlayer insulating layer 19 comprises, for example, silicon oxide or silicon nitride.

The wiring chip 102 can be provided with a multilayer wiring layer for electrically connecting the plurality of transistors TR provided in the transistor chip 101.

The metal pad 21 is surrounded by the second interlayer insulating layer 29. The metal pad 21 is provided in the first direction from the metal pad 11. The metal pad 21 is in contact with the metal pad 11. The metal pad 21 is electrically connected to the metal pad 11.

The interface between the metal pad 21 and the metal pad 11 is at the bonding interface BI and may be considered part of the bonding interface BI.

The metal pad 21 is in contact with the third conductive layer 25. The metal pad 21 is electrically connected to the third conductive layer 25.

As illustrated in FIG. 2, the metal pad 21 includes a barrier metal film 21a and a metal unit 21b. The barrier metal film 21a is provided between the metal unit 21b and the third conductive layer 25 and between the metal unit 21b and the second interlayer insulating layer 29.

The metal pad 21 comprises a metal. The metal unit 21b of the metal pad 21 comprises, for example, copper (Cu). The metal unit 21b of the metal pad 21 is, for example, copper (Cu).

The barrier metal film 21a of the metal pad 21 comprises, for example, a metal or metal nitride. In some examples, barrier metal film 11a comprises at least one metal element selected from the group consisting of titanium (Ti), tantalum (Ta), manganese (Mn), and cobalt (Co). The barrier metal film 21a is, for example, a titanium film, a titanium nitride film, or a tantalum nitride film.

The metal pad 22 is provided in the second direction from the metal pad 21. The metal pad 22 is surrounded by the second interlayer insulating layer 29.

The metal pad 22 is provided in the first direction from the metal pad 12. The metal pad 22 is in contact with the metal pad 12. The metal pad 22 is electrically connected to the metal pad 12.

The interface between the metal pad 22 and the metal pad 12 is at the bonding interface BI and may be considered part of the bonding interface BI.

The metal pad 22 is in contact with the fourth conductive layer 26. The metal pad 22 is electrically connected to the fourth conductive layer 26.

As illustrated in FIG. 2, the metal pad 22 includes a barrier metal film 22a and a metal unit 22b. The barrier metal film 22a is provided between the metal unit 22b and the fourth conductive layer 26 and between the metal unit 22b and the second interlayer insulating layer 29.

The metal pad 22 comprises a metal. The metal unit 22b of the metal pad 22 comprises, for example, copper (Cu). The metal unit 22b of the metal pad 22 is, for example, copper (Cu).

The barrier metal film 22a of the metal pad 22 comprises, for example, a metal or metal nitride. In some examples, barrier metal film 22a comprises at least one metal element selected from the group consisting of titanium (Ti), tantalum (Ta), manganese (Mn), and cobalt (Co). The barrier metal film 22a is, for example, a titanium film, a titanium nitride film, or a tantalum nitride film.

The metal pad 22 is, for example, the same material as the metal pad 21.

The third conductive layer 25 is provided in the first direction from the metal pad 21. The third conductive layer 25 is a conductor material. The third conductive layer 25 is, for example, a metal. The third conductive layer 25 comprises, for example, copper (Cu) or tungsten (W).

The fourth conductive layer 26 is provided in the first direction from the metal pad 22. The fourth conductive layer 26 is a conductor material. The fourth conductive layer 26 is, for example, a metal. The fourth conductive layer 26 comprises, for example, copper (Cu) or tungsten (W).

The external connection electrode pad 28 is provided on the front surface of the wiring chip 102. The external connection electrode pad 28 is provided for electrically connecting the wiring chip 102 and the outside. The external connection electrode pad 28 is connected, for example, to a source or a drain of the transistor TR of the transistor chip 101 via the wiring chip 102.

The second interlayer insulating layer 29 has, for example, a function of providing electrical insulation in the wiring chip 102. The second interlayer insulating layer 29 is an insulator material. The second interlayer insulating layer 29 comprises, for example, silicon oxide or silicon nitride.

The second interlayer insulating layer 29 is in contact with the first interlayer insulating layer 19. The interface between the second interlayer insulating layer 29 and the first interlayer insulating layer 19 is the bonding interface BI.

As illustrated in FIG. 2, the first thickness (t1 in FIG. 2) of the metal pad 11 in the first direction is thinner than the second thickness (t2 in FIG. 2) of the metal pad 12 in the first direction. The first thickness t1 is represented by, for example, the maximum thickness of the metal pad 11 in cross section. The second thickness t2 is represented by, for example, the maximum thickness of the metal pad 12 in cross section.

The first thickness t1 of the metal pad 11 in the first direction is, for example, equal to the distance from the bonding interface BI to the first conductive layer 15. The second thickness t2 of the metal pad 12 in the first direction is, for example, equal to the distance from the bonding interface BI to the second conductive layer 16.

The second thickness t2 of the metal pad 12 is, for example, 1.5 times to 10 times of the first thickness t1 of the metal pad 11.

FIG. 3 is a plan view illustrating a front surface of the bonding interface BI on the transistor chip 101 side. As illustrated in FIG. 3, the first area (S1 in FIG. 3) of the metal pad 11 on the bonding interface BI is larger than the second area (S2 in FIG. 3) of the metal pad 12 on the bonding interface BI.

For example, when the metal pad 11 has a rectangular shape, the first area S1 of the metal pad 11 on the bonding interface BI is a product of a width (w1a in FIG. 3) of the metal pad 11 in the second direction and a width (w1b in FIG. 3) in the third direction. In addition, for example, when the metal pad 12 has a rectangular shape, the second area S2 of the metal pad 12 on the bonding interface BI is a product of a width (w2a in FIG. 3) of the metal pad 12 in the second direction and a width (w2b in FIG. 3) in the third direction.

The width w1a of the metal pad 11 in the second direction is, for example, larger than the width w2a of the metal pad 12 in the second direction. The width w1b of the metal pad 11 in the third direction is, for example, larger than the width w2b of the metal pad 12 in the third direction.

The volume of the metal pad 11 is, for example, 80% to 120% of the volume of the metal pad 12.

The volume of the metal pad 11 is, for example, the product of the first thickness t1 of the metal pad 11 and the first area S1 of the metal pad 11. The volume of the metal pad 12 is, for example, the product of the second thickness t2 of the metal pad 12 and the second area S2 of the metal pad 12.

For example, the product of the first thickness t1 of the metal pad 11 and the first area S1 of the metal pad 11 is 80% to 120% of the product of the second thickness t2 of the metal pad 12 in and the second area S2 of the metal pad 12.

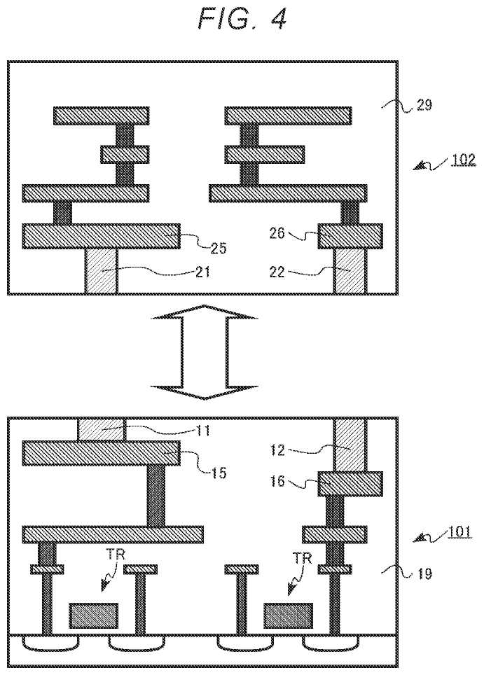

FIG. 4 is an explanatory diagram illustrating a method of manufacturing a semiconductor device according to the first embodiment. FIG. 4 is an explanatory diagram illustrating aspects of a method of manufacturing the logic IC 100.

By using a known semiconductor manufacturing process, a first wafer in which a plurality of regions each corresponding to the transistor chip 101 are formed can be manufactured. In addition, a second wafer in which a plurality of regions each corresponding to the wiring chip 102 are formed can be manufactured using known techniques.

As illustrated in FIG. 4, the first wafer and the second wafer are bonded to each other so that the metal pad 11 of the transistor chip 101 and the metal pad 21 of the wiring chip 102 face each other. Next, by performing a heat treatment, a region corresponding to the transistor chip 101 and a region corresponding to the wiring chip 102 are bonded to each other.

Next, the external connection electrode pad 28 is formed on the front surface of the region corresponding to the wiring chip 102. Thereafter, by dicing the first wafer and the second wafer after they have been bonded to each other, a plurality of logic ICs 100 are manufactured.

Next, the action and the effect of the semiconductor device according to the first embodiment are described.

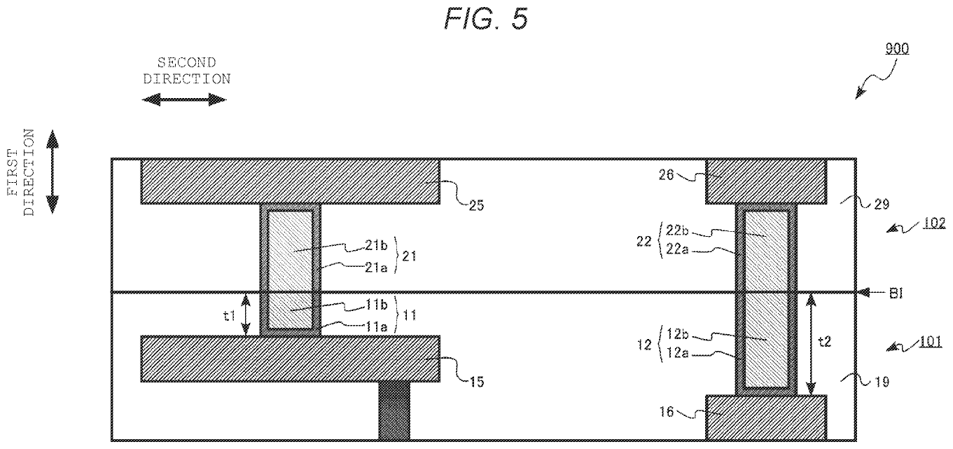

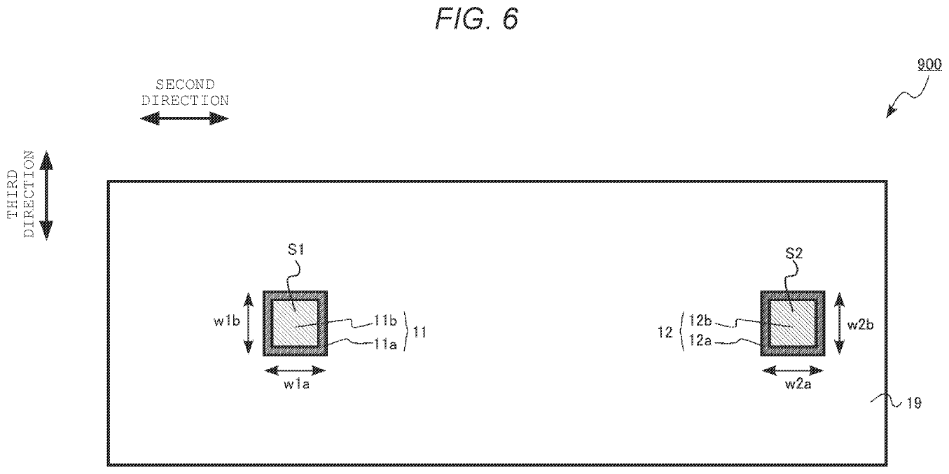

FIG. 5 is an enlarged schematic cross-sectional view illustrating a portion of a semiconductor device according to a comparative example. FIG. 6 is a plan view of the semiconductor device according to the comparative example on the bonding interface. FIG. 5 is a diagram corresponding to FIG. 2 according to the first embodiment. FIG. 6 is a diagram corresponding to FIG. 3 according to the first embodiment.

The semiconductor device according to the comparative example is a logic IC 900. The logic IC 900 according to the comparative example includes a transistor chip 101 and a wiring chip 102.

As illustrated in FIG. 5, in the logic IC 900, similar to the logic IC 100, the first thickness (t1 in FIG. 5) of the metal pad 11 in the first direction is thinner than second thickness (t2 in FIG. 5) of the metal pad 12 in the first direction.

However, as illustrated in FIG. 6, in the logic IC 900 according to the comparative example, the first area (S1 in FIG. 6) of the metal pad 11 on the bonding interface BI is equal to the second area (S2 in FIG. 6) of the metal pad 12 at the bonding interface BI, which is unlike the logic IC 100 according to the first embodiment.

The width (w1a in FIG. 6) of the metal pad 11 in the second direction is, for example, equal to the width (w2a in FIG. 6) of the metal pad 12 in the second direction. In addition, the width (w1b in FIG. 6) of the metal pad 11 in the third direction is equal to the width (w2b in FIG. 6) of the metal pad 12 in the third direction.

In the logic IC 900 according to the comparative example, the volume of the metal pad 11 is smaller than the volume of the metal pad 12.

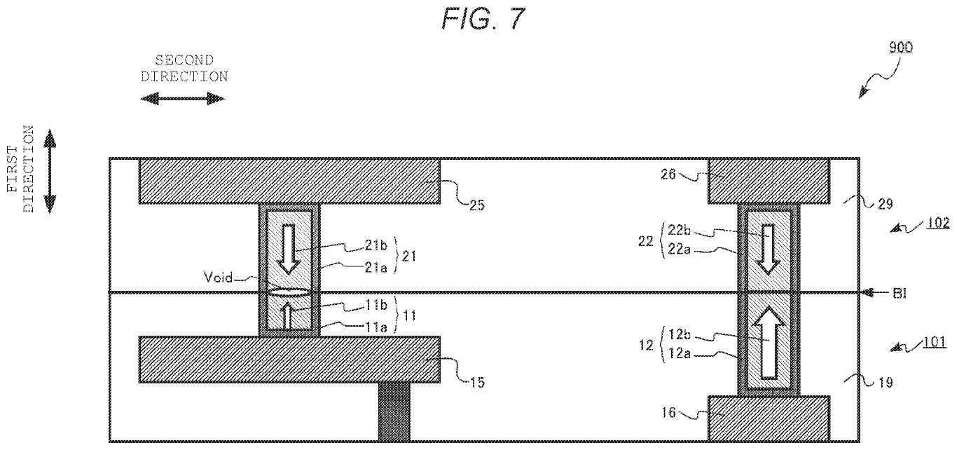

FIG. 7 is an explanatory diagram of a potential problem of the semiconductor device according to the comparative example. FIG. 7 is a cross-sectional view generally corresponding to FIG. 5.

FIG. 7 illustrates a state in which the heat treatment is performed in the manufacturing of the logic IC 900 according to the comparative example. The relative sizes of the white arrows in the drawing indicate the relative amount of an expansion of the metal pads in the heat treatment.

In the logic IC 900, the volume of the metal pad 11 is smaller than the volume of the metal pad 12. Accordingly, the expansion of the metal pad 11 in the heat treatment is less than the expansion of the metal pad 12 in the heat treatment.

Therefore, as illustrated in FIG. 7, a gap (void) may be formed between the metal pad 11 and the metal pad 21, and thus a bonding defect between the metal pad 11 and the metal pad 21 may occur. Accordingly, the bonding of the transistor chip 101 and the wiring chip 102 may be deteriorated.

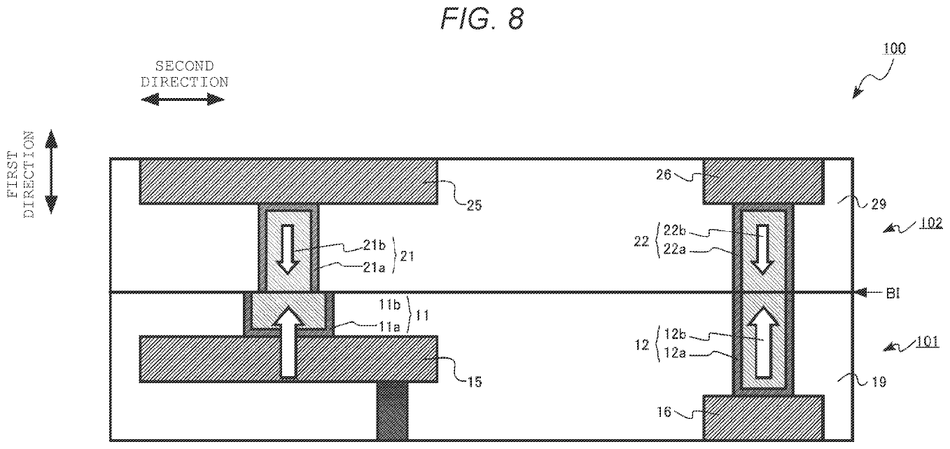

FIG. 8 is an explanatory diagram of the action and the effect of the semiconductor device according to the first embodiment. FIG. 8 is a cross-sectional view generally corresponding to FIG. 2.

In the logic IC 100 according to the first embodiment, the first area (S1 in FIG. 3) of the metal pad 11 at the bonding interface BI is larger than the second area (S2 in FIG. 3) of the metal pad 12 at the bonding interface BI. Therefore, the volume of the metal pad 11 is larger than in the logic IC 900 of the comparative example.

Therefore, as illustrated in FIG. 8, the expansion of the metal pad 11 in the heat treatment is increased and thus becomes closer to the amount of expansion of the metal pad 12 in the heat treatment. Therefore, the occurrence of the bonding defect between the metal pad 11 and the metal pad 21 can be prevented. Therefore, the bonding between the transistor chip 101 and the wiring chip 102 is improved.

In view of causing the amount of expansion of the metal pad 11 and the metal pad 12 in the heat treatment to be close to each other to prevent the occurrence of bonding defect between the metal pad 11 and the metal pad 21, the volume of the metal pad 11 is preferably 80% to 120% of the volume of the metal pad 12 and more preferably 90% to 110%.

The first thickness t1 of the metal pad 11 in the first direction multiplied by the first area S1 of the metal pad 11 is preferably 80% to 120% of the value of the second thickness t2 of the metal pad 12 in the first direction multiplied by the second area S2 of the metal pad 12 and is more preferably 90% to 110%.

In view of preventing the occurrence of the bonding defect between the metal pad 11 and the metal pad 21, the product of the first thickness t1 and the first area S1 of the metal pad 11 is preferably greater than the product of the second thickness t2 and the second area S2 of the metal pad 12. In some examples, the metal pads are formed by depositing a metal film and then planarizing the metal film by using a chemical mechanical polishing method (CMP method). A so-called “dishing” phenomenon in which a recess is formed on the surface of the metal pad may occur in planarization by the CMP is a known issue.

When dishing occurs, the volume of the metal pad before bonding is reduced. Generally, dishing is more likely to occur when the planar area of the metal pad is large. Therefore, in view of compensating for the reduced volume of the metal pad caused by dishing, the product of the first thickness t1 and the first area S1 of the metal pad 11 may be preferably set to be larger than the product of the second thickness t2 and the second area S2 of the metal pad 12.

According to the first embodiment, a semiconductor device can be provided for which bonding defects of the metal pad can be prevented, and thus the bonding characteristics can be improved.

### Second Embodiment

A semiconductor device according to a second embodiment is different from the semiconductor device according to the first embodiment in that the second chip further includes a fifth electrode in contact with the first electrode.

The semiconductor device according to the second embodiment is a logic IC 200.

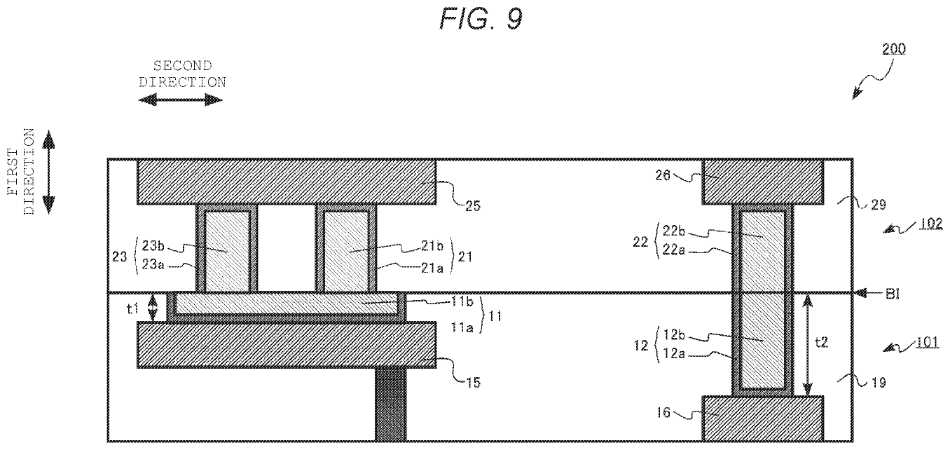

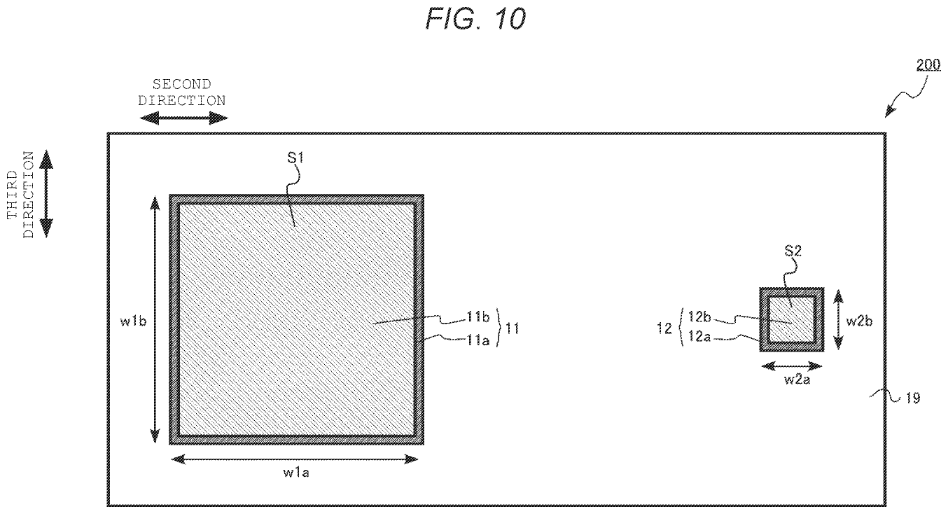

FIG. 9 is an enlarged schematic cross-sectional view illustrating a portion of the semiconductor device according to the second embodiment. FIG. 10 is a schematic plan view illustrating the semiconductor device according to the second embodiment. FIG. 10 is a plan view illustrating the semiconductor device according to the second embodiment on the bonding interface.

FIG. 9 is a diagram corresponding to FIG. 2 according to the first embodiment. FIG. 10 is a diagram corresponding to FIG. 3 according to the first embodiment.

The logic IC 200 according to the second embodiment includes the transistor chip 101 and the wiring chip 102. The transistor chip 101 is an example of the first chip. The wiring chip 102 is an example of the second chip.

The transistor chip 101 includes the plurality of transistors TR, the metal pad 11, the metal pad 12, the first conductive layer 15, the second conductive layer 16, and the first interlayer insulating layer 19. The metal pad 11 is an example of the first electrode. The metal pad 12 is an example of the second electrode.

The wiring chip 102 includes the metal pad 21, the metal pad 22, a metal pad 23, the third conductive layer 25, the fourth conductive layer 26, the external connection electrode pad 28, and the second interlayer insulating layer 29. The metal pad 21 is an example of the third electrode. The metal pad 22 is an example of the fourth electrode. The metal pad 23 is an example of the fifth electrode.

The metal pad 23 is provided in the second direction from the metal pad 21. The metal pad 23 is surrounded by the second interlayer insulating layer 29.

The metal pad 23 is provided in the first direction from the metal pad 11. The metal pad 23 is in contact with the metal pad 11. The metal pad 23 is electrically connected to the metal pad 11.

Two metal pads including the metal pad 21 and the metal pad 23 are bonded to the metal pad 11.

The interface between the metal pad 23 and the metal pad 11 is the bonding interface BI.

The metal pad 23 is in contact with the third conductive layer 25. The metal pad 23 is electrically connected to the third conductive layer 25.

As illustrated in FIG. 9, the metal pad 23 includes a barrier metal film 23a and a metal unit 23b. The barrier metal film 23a is provided between the metal unit 23b and the third conductive layer 25 and between the metal unit 23b and the second interlayer insulating layer 29.

The metal pad 23 comprises a metal. The metal unit 23b of the metal pad 23 comprises, for example, copper (Cu). The metal unit 23b of the metal pad 23 is, for example, copper (Cu).

The barrier metal film 23a of the metal pad 23 comprises, for example, a metal or metal nitride. In some examples, barrier metal film 23a comprises at least one metal element selected from the group consisting of titanium (Ti), tantalum (Ta), manganese (Mn), and cobalt (Co). The barrier metal film 23a is, for example, a titanium film, a titanium nitride film, or a tantalum nitride film.

The metal pad 23 can be the same material as the metal pad 21 and the metal pad 22.

In a manner similar to the logic IC 100, the logic IC 200, as illustrated in FIG. 10, the first area (S1 in FIG. 10) of the metal pad 11 on the bonding interface BI is larger than the second area (S2 in FIG. 10) of the metal pad 12 at the bonding interface BI. Therefore, the occurrence of the bonding defect between the metal pad 11 and the metal pad 21 or between the metal pad 11 and the metal pad 23 is prevented. Therefore, the bonding characteristics between the transistor chip 101 and the wiring chip 102 are improved.

In addition, in the logic IC 200, two metal pads are bonded to the metal pad 11. Therefore, the bonding characteristics between the transistor chip 101 and the wiring chip 102 are improved.

Modification

A semiconductor device according to a modification of the second embodiment is different in that the first thickness of the first electrode in the first direction perpendicular to the bonding interface between the first chip and the second chip is equal to the second thickness of the second electrode in the first direction.

The semiconductor device according to the modification of the second embodiment is a logic IC 201.

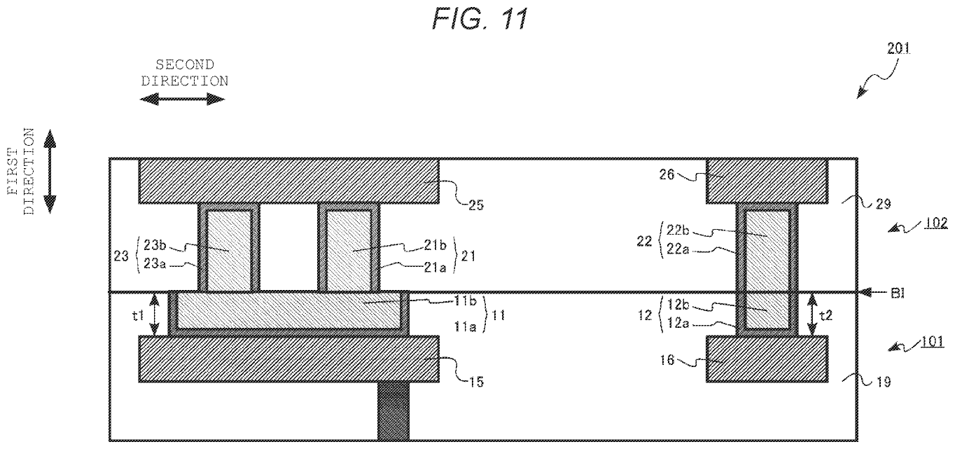

FIG. 11 is an enlarged schematic cross-sectional view illustrating a portion of the semiconductor device according to the modification of the second embodiment. FIG. 11 is a diagram generally corresponding to FIG. 9 for the second embodiment.

As illustrated in FIG. 11, the first thickness (t1 in FIG. 11) of the metal pad 11 in the first direction is equal to the second thickness (t2 in FIG. 11) of the metal pad 12 in the first direction.

In the logic IC 201, two metal pads are bonded to the metal pad 11. Therefore, the bonding characteristics between the transistor chip 101 and the wiring chip 102 are improved.

With the above, a semiconductor device can be provided for which bonding defects of metal pads can be prevented, and thus bonding characteristics can be improved.

### Third Embodiment

A semiconductor device according to a third embodiment is different from the semiconductor device according to the first embodiment in that the first chip further includes a sixth electrode, the second chip further includes a seventh electrode that is in contact with the sixth electrode, the second thickness is less than the third thickness of the sixth electrode in the first direction, and the second area is larger than the third area of the sixth electrode at the bonding interface.

The semiconductor device according to the third embodiment is a logic IC 300.

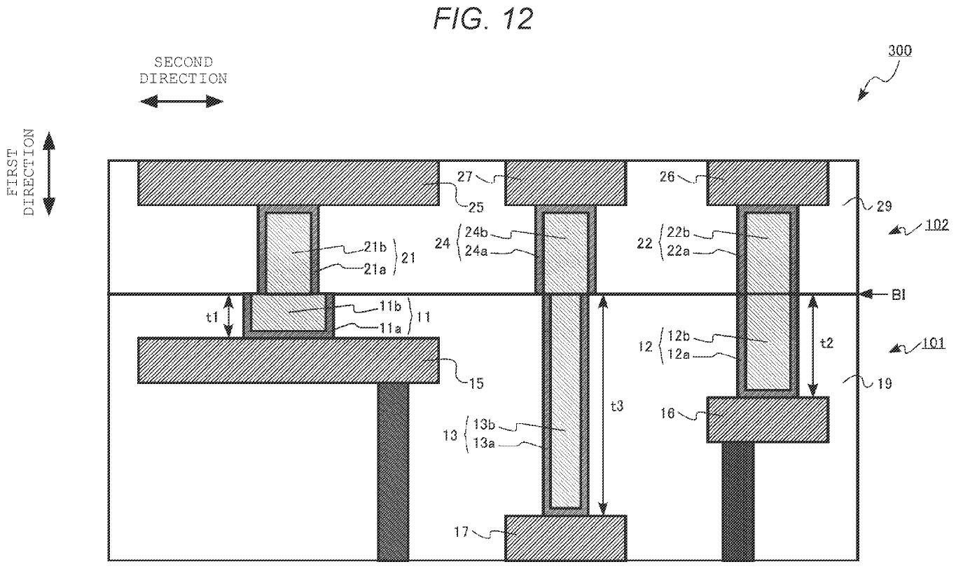

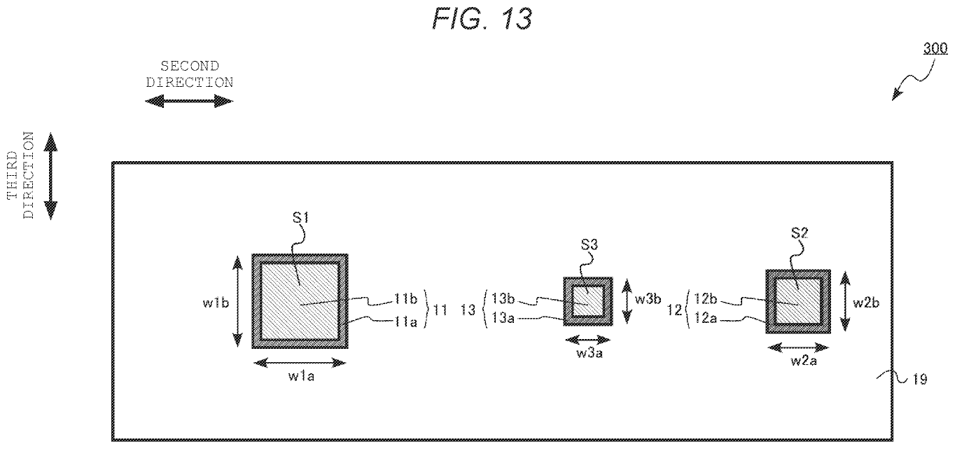

FIG. 12 is an enlarged schematic cross-sectional view illustrating a portion of the semiconductor device according to the third embodiment. FIG. 13 is a schematic plan view illustrating the semiconductor device according to the third embodiment. FIG. 13 is a plan view illustrating the semiconductor device according to the third embodiment at the bonding interface.

FIG. 12 is a diagram corresponding to FIG. 2 according to the first embodiment. FIG. 13 is a diagram corresponding to FIG. 3 according to the first embodiment.

The logic IC 300 according to the third embodiment includes the transistor chip 101 and the wiring chip 102. The transistor chip 101 is an example of the first chip. The wiring chip 102 is an example of the second chip.

The transistor chip 101 includes the plurality of transistors TR, the metal pad 11, the metal pad 12, a metal pad 13, the first conductive layer 15, the second conductive layer 16, a fifth conductive layer 17, and the first interlayer insulating layer 19. The metal pad 11 is an example of the first electrode. The metal pad 12 is an example of the second electrode. The metal pad 13 is an example of the sixth electrode.

The wiring chip 102 includes the metal pad 21, the metal pad 22, a metal pad 24, the third conductive layer 25, the fourth conductive layer 26, a sixth conductive layer 27, the external connection electrode pad 28, and the second interlayer insulating layer 29. The metal pad 21 is an example of the third electrode. The metal pad 22 is an example of the fourth electrode. The metal pad 24 is an example of the seventh electrode.

The metal pad 13 is provided in the second direction from the metal pad 11. The metal pad 13 is surrounded by the first interlayer insulating layer 19. The metal pad 13 is in contact with the fifth conductive layer 17. The metal pad 13 is electrically connected to the fifth conductive layer 17.

As illustrated in FIGS. 12 and 13, the metal pad 13 includes a barrier metal film 13a and a metal unit 13b. The barrier metal film 13a is provided between the metal unit 13b and the fifth conductive layer 17 and between the metal unit 13b and the first interlayer insulating layer 19.

The metal pad 13 comprises metal. The metal unit 13b of the metal pad 13 comprises, for example, copper (Cu). The metal unit 13b of the metal pad 13 is, for example, copper (Cu).

The barrier metal film 13a of the metal pad 13 comprises, for example, a metal or metal nitride. In some examples, barrier metal film 13a comprises, at least one metal element selected from the group consisting of titanium (Ti), tantalum (Ta), manganese (Mn), and cobalt (Co). The barrier metal film 13a is, for example, a titanium film, a titanium nitride film, or a tantalum nitride film.

The metal pad 13 can be the same material as the metal pad 11 and/or the metal pad 12.

The fifth conductive layer 17 can be electrically connected to the source or the drain of the transistor TR.

The fifth conductive layer 17 is provided in the first direction from the metal pad 13. The fifth conductive layer 17 is a conductor material. The fifth conductive layer 17 is, for example, a metal. The fifth conductive layer 17 comprises, for example, copper (Cu) or tungsten (W).

The metal pad 24 is provided in the second direction from the metal pad 21. The metal pad 24 is surrounded by the second interlayer insulating layer 29.

The metal pad 24 is provided in the first direction from the metal pad 13. The metal pad 24 is in contact with the metal pad 13. The metal pad 24 is electrically connected to the metal pad 13.

The interface between the metal pad 24 and the metal pad 13 is the bonding interface BI.

The metal pad 24 is in contact with the sixth conductive layer 27. The metal pad 24 is electrically connected to the sixth conductive layer 27.

As illustrated in FIG. 12, the metal pad 24 includes a barrier metal film 24a and a metal unit 24b. The barrier metal film 24a is provided between the metal unit 24b and the sixth conductive layer 27 and between the metal unit 24b and the second interlayer insulating layer 29.

The metal pad 24 comprises a metal. The metal unit 24b of the metal pad 24 comprises, for example, copper (Cu). The metal unit 24b of the metal pad 24 is, for example, copper (Cu).

The barrier metal film 24a of the metal pad 24 comprises, for example, a metal or metal nitride. In some examples, barrier metal film 24a comprise at least one metal element selected from the group consisting of titanium (Ti), tantalum (Ta), manganese (Mn), and cobalt (Co). The barrier metal film 24a is, for example, a titanium film, a titanium nitride film, or a tantalum nitride film.

The metal pad 24 can be the same material as the metal pad 21 and/or the metal pad 22.

The sixth conductive layer 27 is provided in the first direction from the metal pad 24. The sixth conductive layer 27 is a conductor material. The sixth conductive layer 27 is, for example, a metal. The sixth conductive layer 27 comprises, for example, copper (Cu) or tungsten (W).

As illustrated in FIG. 12, the first thickness (t1 in FIG. 12) of the metal pad 11 in the first direction is thinner than the second thickness (t2 in FIG. 12) of the metal pad 12 in the first direction. The first thickness t1 of the metal pad 11 in the first direction is, for example, equal to the distance from the bonding interface BI to the first conductive layer 15. The second thickness t2 of the metal pad 12 in the first direction is, for example, equal to the distance from the bonding interface BI to the second conductive layer 16.

In addition, as illustrated in FIG. 12, the second thickness t2 of the metal pad 12 in the first direction is thinner than a third thickness (t3 in FIG. 12) of the metal pad 13 in the first direction. The third thickness t3 is represented by, for example, the maximum thickness of the metal pad 13 in cross section. The third thickness t3 of the metal pad 13 in the first direction is, for example, equal to the distance from the bonding interface BI to the fifth conductive layer 17.

The second thickness t2 of the metal pad 12 is, for example, 1.5 times to 10 times of the first thickness t1 of the metal pad 11. The third thickness t3 of the metal pad 12 is, for example, 1.5 times to 10 times of the first thickness t1 of the metal pad 11.

FIG. 13 is a plan view illustrating a front surface of the bonding interface BI on the transistor chip 101 side. As illustrated in FIG. 13, the first area (S1 in FIG. 13) of the metal pad 11 on the bonding interface BI is larger than the second area (S2 in FIG. 13) of the metal pad 12 on the bonding interface BI. The second area S2 of the metal pad 13 on the bonding interface BI is larger than the third area (S3 in FIG. 13) of the metal pad 13 on the bonding interface BI.

For example, when the metal pad 11 has a rectangular shape, the first area S1 of the metal pad 11 on the bonding interface BI is a product of a width (w1a in FIG. 13) of the metal pad 11 in the second direction and a width (w1b in FIG. 13) in the third direction. In addition, for example, when the metal pad 12 has a rectangular shape, the second area S2 of the metal pad 12 on the bonding interface BI is a product of the width (w2a in FIG. 13) of the metal pad 12 in the second direction and the width (w2b in FIG. 13) in the third direction. In addition, for example, when the metal pad 13 has a rectangular shape, a third area S3 of the metal pad 13 on the bonding interface BI is a product of a width (w3a in FIG. 13) of the metal pad 13 in the second direction and a width (w3b in FIG. 13) in the third direction.

The width w1a of the metal pad 11 in the second direction is, for example, larger than the width w2a of the metal pad 12 in the second direction. The width w1b of the metal pad 11 in the third direction is, for example, larger than the width w2b of the metal pad 12 in the third direction.

The width w2a of the metal pad 12 in the second direction is, for example, larger than the width w3a of the metal pad 13 in the second direction. The width w2b of the metal pad 12 in the third direction is, for example, larger than the width w3b of the metal pad 13 in the third direction.

The volume of the metal pad 11 is, for example, 80% to 120% of the volume of the metal pad 12.

The volume of the metal pad 11 can be taken as the product of the first thickness t1 in the first direction of the metal pad 11 and the first area S1 of the metal pad 11. The volume of the metal pad 12 can be taken as the product of the second thickness t2 in the first direction of the metal pad 12 and the second area S2 of the metal pad 12.

For example, the product of the first thickness t1 of the metal pad 11 and the first area S1 of the metal pad 11 is 80% to 120% of the product of the second thickness t2 of the metal pad 12 and the second area S2 of the metal pad 12.

The volume of the metal pad 12 is, for example, 80% to 120% of the volume of the metal pad 13.

The volume of the metal pad 13 is, for example, the product of the third thickness t3 in the first direction of the metal pad 13 and the third area S3 of the metal pad 13.

For example, the product of the second thickness t2 of the metal pad 12 and the second area S2 of the metal pad 12 is 80% to 120% of the product of the third thickness t3 of the metal pad 13 and the third area S3 of the metal pad 13.

According to the third embodiment, a semiconductor device can be provided for which bonding defects of the metal pads can be prevented, and thus the bonding characteristics can be improved.

### Fourth Embodiment

A semiconductor storage device according to a fourth embodiment includes a first chip that includes a first memory cell array including a plurality of first gate electrode layers stacked in the first direction, a first semiconductor layer extending in the first direction, and a first charge storage layer provided between the first semiconductor layer and at least one first gate electrode layer among the plurality of first gate electrode layers, a second semiconductor layer provided in the first direction from the first memory cell array and in contact with the first semiconductor layer, a first conductive layer provided in a second direction perpendicular to the first direction from the first memory cell array and extending in the first direction, a first electrode in contact with the second semiconductor layer, and a second electrode in contact with the first conductive layer; and a second chip that includes a third electrode in contact with the first electrode and a fourth electrode in contact with the second electrode and is bonded to the first chip, in which a first thickness of the first electrode in the first direction is thinner than a second thickness of the second electrode in the first direction, and a first area of the first electrode on a bonding interface between the first chip and the second chip is larger than a second area of the second electrode on the bonding interface.

The semiconductor storage device according to the fourth embodiment is different from the semiconductor storage device according to the first embodiment in that the first chip includes a memory cell array.

The semiconductor device according to the fourth embodiment is a nonvolatile semiconductor memory 400. The nonvolatile semiconductor memory 400 is, for example, a three-dimensional NAND flash memory in which memory cells are three dimensionally arranged.

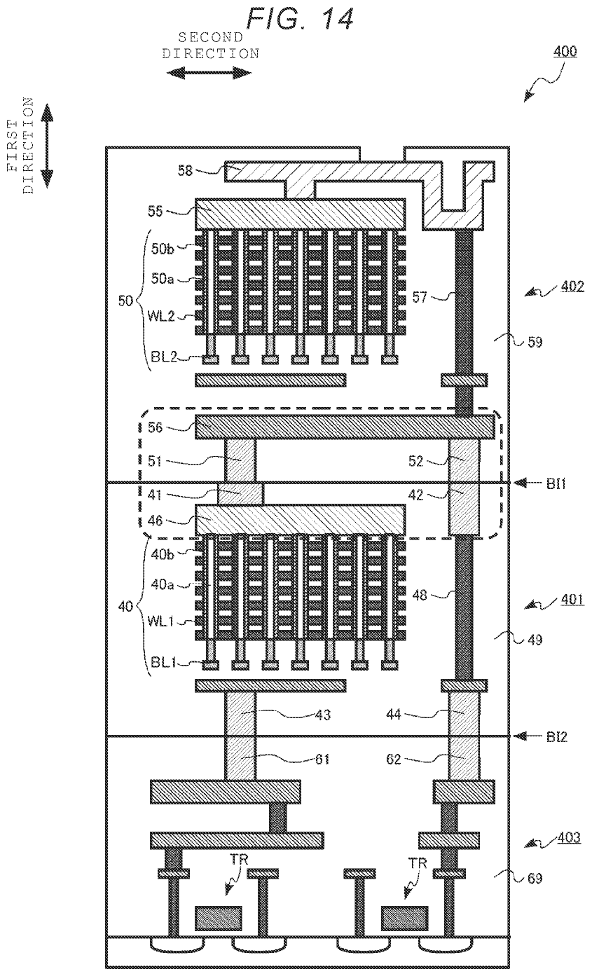

FIG. 14 is a schematic cross-sectional view illustrating the semiconductor storage device according to the fourth embodiment.

The nonvolatile semiconductor memory 400 according to the fourth embodiment includes a first memory chip 401, a second memory chip 402, and a controller chip 403. The first memory chip 401 is an example of a first chip. The second memory chip 402 is an example of a second chip. The controller chip 403 is an example of a third chip.

The first memory chip 401 includes a first memory cell array 40, a metal pad 41, a metal pad 42, a metal pad 43, a metal pad 44, a first source semiconductor layer 46, a first conductive layer 48, and a first interlayer insulating layer 49. The metal pad 41 is an example of a first electrode. The metal pad 42 is an example of a second electrode. The metal pad 44 is an example of a sixth electrode. The first source semiconductor layer 46 is an example of a second semiconductor layer.

The first memory cell array 40 includes a first channel semiconductor layer 40a, a first charge storage layer 40b, a plurality of first word lines WL1, and a plurality of first bit lines BL1. The first channel semiconductor layer 40a is an example of the first semiconductor layer. The first word lines WL1 are an example of a first gate electrode layer.

The second memory chip 402 includes a second memory cell array 50, a metal pad 51, a metal pad 52, a second source semiconductor layer 55, a second conductive layer 56, a third conductive layer 57, an external connection electrode pad layer 58, and a second interlayer insulating layer 59. The metal pad 51 is an example of a third electrode. The metal pad 52 is an example of a fourth electrode. The second source semiconductor layer 55 is an example of a fourth semiconductor layer.

The second memory cell array 50 includes a second channel semiconductor layer 50a, a second charge storage layer 50b, a plurality of second word lines WL2, and a plurality of second bit lines BL2. The second channel semiconductor layer 50a is an example of a third semiconductor layer. The second word line WL2 is an example of a second gate electrode layer.

The controller chip 403 includes a plurality of transistors TR, a metal pad 61, a metal pad 62, and a third interlayer insulating layer 69. The metal pad 62 is an example of a fifth electrode.

The first memory chip 401 and the second memory chip 402 are bonded to each other at a first bonding interface BI1. The first memory chip 401 and the controller chip 403 are bonded to each other at a second bonding interface BI2. The first memory chip 401 and the second memory chip 402, and the first memory chip 401 and the controller chip 403 are bonded to each other, for example, by using a so-called hybrid bonding technology, in which an electrode and an insulating layer are bonded to each other.

The first memory chip 401 is provided between the second memory chip 402 and the controller chip 403.

The direction in which the first channel semiconductor layer 40a extends is referred to as the first direction and is a direction perpendicular to the first bonding interface BI1 and the second bonding interface BI2. A direction perpendicular to the first direction is referred to as the second direction, and a direction perpendicular to the first direction and the second direction is referred to as the third direction.

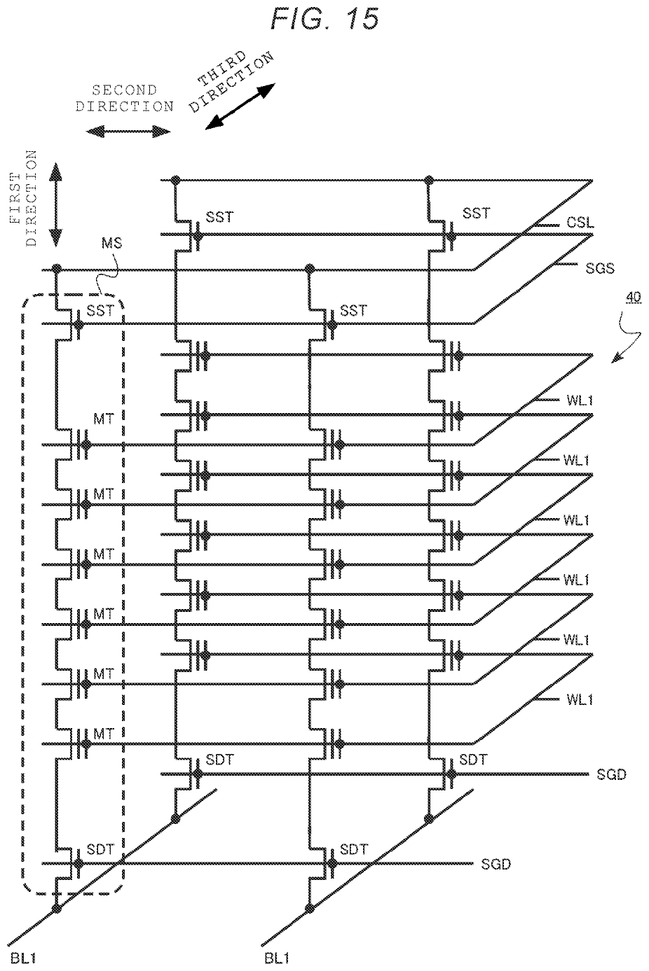

FIG. 15 is a circuit diagram of the first memory cell array of the semiconductor storage device according to the fourth embodiment.

As illustrated in FIG. 15, the first memory cell array 40 includes a plurality of first bit lines BL1, a plurality of drain select gate lines SGD, a plurality of first word lines WL1, a source select gate line SGS, and a plurality of memory strings MS. A common source line CSL is provided in the first direction from the first memory cell array 40.

The plurality of first word lines WL1 are spaced from each other and stacked in the first direction. The plurality of memory strings MS extend in the first direction. The plurality of first bit lines BL1 extend, for example, in the third direction.

As illustrated in FIG. 15, each memory string MS includes a drain select transistor SDT, a plurality of memory cells, and a source select transistor SST, which are connected to each other in series between the first bit line BL1 and the common source line CSL.

A memory string MS can be selected by selecting one first bit line BL1 and one drain select gate line SGD, and a memory cell on the memory string MS can be selected by further selecting one first word line WL1. Each first word line WL1 is a gate electrode of a memory cell transistor MT that forms a memory cell.

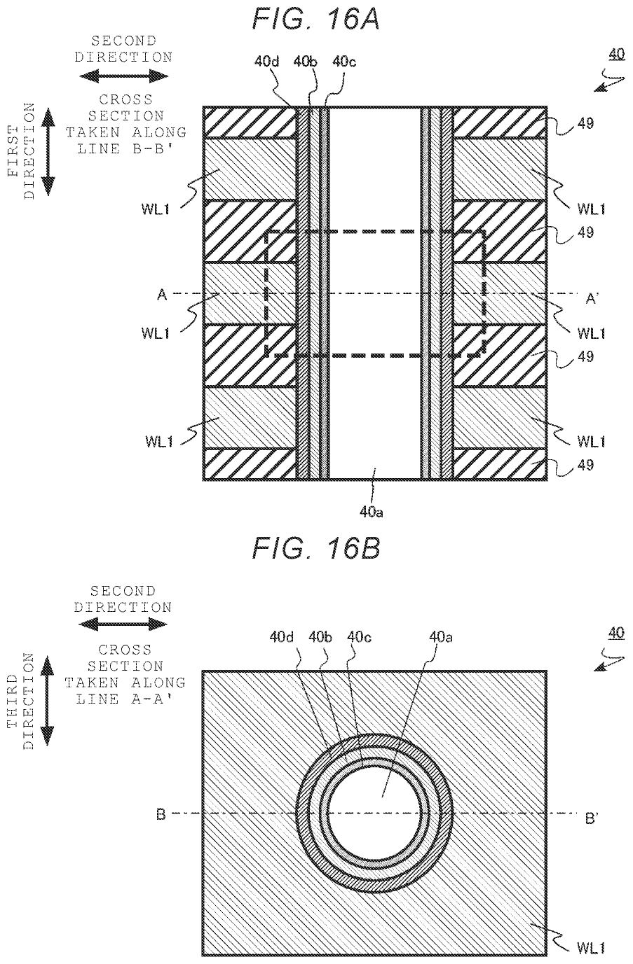

FIGS. 16A and 16B are schematic cross-sectional views illustrating the first memory cell array of the semiconductor storage device according to the fourth embodiment. FIGS. 16A and 16B illustrate cross sections of the plurality of memory cells of the memory string MS in the first memory cell array 40 surrounded by the dotted line of FIG. 15.

FIG. 16A is a cross section taken along the line B-B′ of FIG. 16B. FIG. 16B is a cross section taken along the line A-A′ of FIG. 16A. In FIG. 16A, a region surrounded by a broken line is one memory cell.

As illustrated in FIGS. 16A and 16B, the first memory cell array 40 includes a first channel semiconductor layer 40a, a first charge storage layer 40b, a tunnel insulating layer 40c, a block insulating layer 40d, a plurality of first word lines WL1, a plurality of first bit lines BL1, and a first interlayer insulating layer 49.

The first channel semiconductor layer 40a extends in the first direction. The first channel semiconductor layer 40a is surrounded by the plurality of first word lines WL1. The first channel semiconductor layer 40a is, for example, cylindrical (e.g., columnar or pillar). The first channel semiconductor layer 40a functions as a channel of the memory cell transistors MT.

The first channel semiconductor layer 40a is, for example, a polycrystalline semiconductor. The first channel semiconductor layer 40a is, for example, polycrystalline silicon.

The first charge storage layer 40b is provided between the first channel semiconductor layer 40a and each first word line WL1. The first charge storage layer 40b extends, for example, in the first direction. The first charge storage layer 40b is provided between the tunnel insulating layer 40c and the block insulating layer 40d.

The first charge storage layer 40b has a function of accumulating charges. The charge is, for example, an electron. The threshold voltage of the memory cell transistor MT changes according to the amount of charges accumulated in the first charge storage layer 40b. By using the change of the threshold voltage, one memory cell can store data.

For example, the change of the threshold voltage of the memory cell transistor MT changes the voltage that turns on the memory cell transistor MT. For example, when a state in which the threshold voltage is high is defined as data of “0”, and a state in which the threshold voltage is low is defined as data of “1”, the memory cell can store 1-bit data of “0” and “1”.

The first charge storage layer 40b comprises, for example, silicon (Si) and nitrogen (N). The first charge storage layer 40b is, for example, silicon nitride.

The tunnel insulating layer 40c has a function of passing charges according to the voltage applied between the first word line WL1 and the first channel semiconductor layer 40a.

The tunnel insulating layer 40c comprises, for example, silicon (Si), nitrogen (N), and oxygen (O). The tunnel insulating layer 40c is, for example, silicon nitride or silicon oxynitride.

The block insulating layer 40d has a function of blocking current flowing between the first charge storage layer 40b and the first word line WL1.

The block insulating layer 40d is, for example, an oxide, an oxynitride, or a nitride. The block insulating layer 40d comprises, for example, silicon (Si) and oxygen (O).

The first word lines WL1 are spaced from each other and repeatedly stacked in the first direction. The first interlayer insulating layer 49 is provided between two first word lines WL1. The first word line WL1 functions as a control electrode of the memory cell transistor MT.

The first word line WL1 is a plate-shaped conductor. The first word line WL1 can be a metal, a metal nitride, a metal carbide, or a semiconductor material. The first word line WL1 is, for example, tungsten (W).

The second memory cell array 50 of the second memory chip 402 includes the second channel semiconductor layer 50a, the second charge storage layer 50b, the plurality of second word lines WL2, the plurality of second bit lines BL2, and the second interlayer insulating layer 59. The second memory cell array 50 also includes the same configuration as the first memory cell array 40 illustrated in FIGS. 15, 16A, and 16B.

The first memory chip 401 includes the first source semiconductor layer 46 that is provided in the first direction from the first memory cell array 40 and is in contact with the first channel semiconductor layer 40a. The first source semiconductor layer 46 functions as the common source line CSL illustrated in FIG. 15.

The first source semiconductor layer 46 comprises a semiconductor material. The first source semiconductor layer 46 comprises, for example, polycrystalline silicon. The first source semiconductor layer 46 is, for example, polycrystalline silicon layer.

The first conductive layer 48 is provided in the second direction from the first memory cell array 40. The first conductive layer 48 extends in the first direction.

The first conductive layer 48 is provided in the first direction from the metal pad 42 and the metal pad 44. The first conductive layer 48 is electrically connected to the metal pad 42 and the metal pad 44. The first conductive layer 48 is in contact with the metal pad 42.

The first conductive layer 48 is a conductor material. The first conductive layer 48 is, for example, a metal. The first conductive layer 48 comprises, for example, tungsten (W).

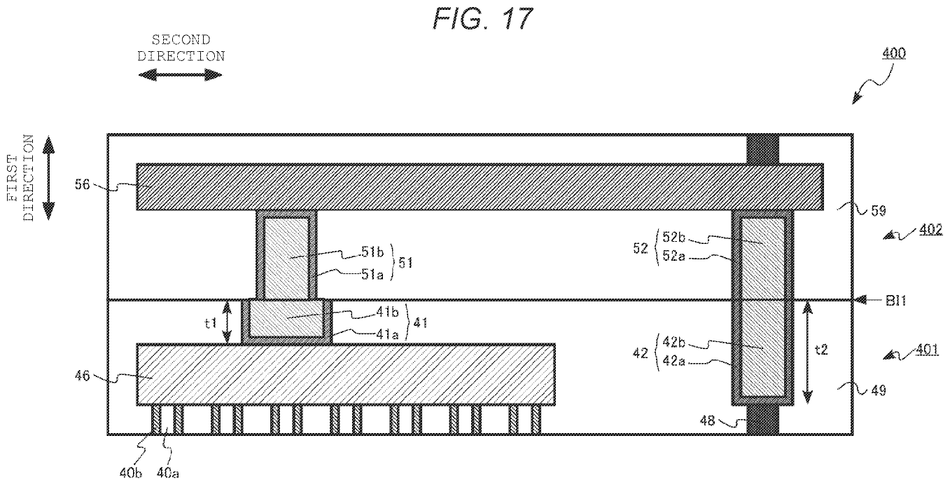

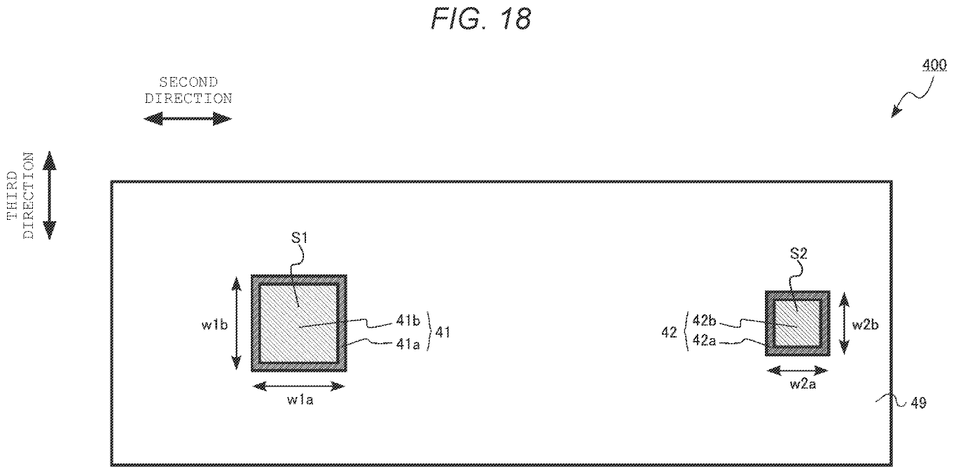

FIG. 17 is an enlarged schematic cross-sectional view illustrating a portion of the semiconductor storage device according to the fourth embodiment. FIG. 17 is a cross-sectional view of a region surrounded by the dotted line in FIG. 14. FIG. 18 is a schematic plan view illustrating the semiconductor storage device according to the fourth embodiment. FIG. 18 is a plan view illustrating the semiconductor storage device according to the fourth embodiment on the first bonding interface BI1.

The metal pad 41 is surrounded by the first interlayer insulating layer 49. The metal pad 41 is in contact with the first source semiconductor layer 46. The metal pad 41 is electrically connected to the first source semiconductor layer 46.

As illustrated in FIGS. 17 and 18, the metal pad 41 includes a barrier metal film 41a and a metal unit 41b. The barrier metal film 41a is provided between the metal unit 41b and the first source semiconductor layer 46 and between the metal unit 41b and the first interlayer insulating layer 49.

The metal pad 41 comprises a metal. The metal unit 41b of the metal pad 41 comprises, for example, copper (Cu). The metal unit 41b of the metal pad 41 is, for example, copper (Cu).

The barrier metal film 41a of the metal pad 41 comprises, for example, a metal or metal nitride. In some examples, barrier metal film 41a comprises at least one metal element selected from the group consisting of titanium (Ti), tantalum (Ta), manganese (Mn), and cobalt (Co). The barrier metal film 41a is, for example, a titanium film, a titanium nitride film, or a tantalum nitride film.

The metal pad 42 is provided in the second direction from the metal pad 41. The metal pad 42 is surrounded by the first interlayer insulating layer 49. The metal pad 42 is in contact with the first conductive layer 48. The metal pad 42 is electrically connected to the first conductive layer 48.

As illustrated in FIGS. 17 and 18, the metal pad 42 includes a barrier metal film 42a and a metal unit 42b. The barrier metal film 42a is provided between the metal unit 42b and the first conductive layer 48 and between the metal unit 42b and the first interlayer insulating layer 49.

The metal pad 42 comprises a metal. The metal unit 42b of the metal pad 42 comprises, for example, copper (Cu). The metal unit 42b of the metal pad 42 is, for example, copper (Cu).

The barrier metal film 42a of the metal pad 42 is, for example, a metal or metal nitride. In some examples, barrier metal film 42a comprises at least one metal element selected from the group consisting of titanium (Ti), tantalum (Ta), manganese (Mn), and cobalt (Co). The barrier metal film 42a is, for example, a titanium film, a titanium nitride film, or a tantalum nitride film.

The metal pad 42 can be the same material as the metal pad 41.

The metal pad 43 is surrounded by the first interlayer insulating layer 49. The metal pad 43 is provided in the first memory chip 401 on the controller chip 403 side. The metal pad 43 is in contact with the metal pad 61 provided in the controller chip 403. The metal pad 43 is electrically connected to the metal pad 61.

The metal pad 44 is surrounded by the first interlayer insulating layer 49. The metal pad 44 is provided in the first memory chip 401 on the controller chip 403 side. The metal pad 44 is electrically connected to the first conductive layer 48. The metal pad 44 is in contact with the metal pad 62 provided in the controller chip 403. The metal pad 44 is electrically connected to the metal pad 62.

The first interlayer insulating layer 49 has, for example, a function of providing electrical insulation in the first memory chip 401. The first interlayer insulating layer 49 is an insulator material. The first interlayer insulating layer 49 comprises, for example, silicon oxide or silicon nitride.

The second memory chip 402 is provided in the first direction from the second memory cell array 50. The second memory chip 402 includes the second source semiconductor layer 55 that is in contact with the second channel semiconductor layer 50a. The second source semiconductor layer 55 functions as the common source line CSL.

The second source semiconductor layer 55 comprises a semiconductor material. The second source semiconductor layer 55 comprises, for example, polycrystalline silicon. The second source semiconductor layer 55 is, for example, polycrystalline silicon layer.

The second conductive layer 56 is provided between the metal pad 51 and the second memory cell array 50. The second conductive layer 56 is in contact, for example, with the metal pad 51 and the metal pad 52. The second conductive layer 56 is electrically connected to the metal pad 51 and the metal pad 52.

The second conductive layer 56 is a conductor material. The second conductive layer 56 is, for example, a metal. The second conductive layer 56 comprises, for example, copper (Cu) or tungsten (W).

The third conductive layer 57 is provided in the second direction from the second memory cell array 50. The third conductive layer 57 extends in the first direction.

The third conductive layer 57 is provided in the first direction from the metal pad 52. The third conductive layer 57 is electrically connected to the metal pad 51, the metal pad 52, the second source semiconductor layer 55, the second conductive layer 56, and the external connection electrode pad layer 58. The third conductive layer 57 is in contact with the external connection electrode pad layer 58.

The third conductive layer 57 is a conductor material. The third conductive layer 57 is, for example, a metal. The third conductive layer 57 comprises, for example, tungsten (W).

The metal pad 51 is surrounded by the second interlayer insulating layer 59. The metal pad 51 is provided in the first direction from the metal pad 41. The metal pad 51 is in contact with the metal pad 41. The metal pad 51 is electrically connected to the metal pad 41.

The interface between the metal pad 51 and the metal pad 41 is the first bonding interface BI1. The metal pad 51 is provided between the first bonding interface BI1 and the second memory cell array 50.

The metal pad 51 is in contact with the second conductive layer 56. The metal pad 51 is electrically connected to the second conductive layer 56.

As illustrated in FIGS. 17 and 18, the metal pad 51 includes a barrier metal film 51a and a metal unit 51b. The barrier metal film 51a is provided between the metal unit 51b and the second conductive layer 56 and between the metal unit 51b and the second interlayer insulating layer 59.

The metal pad 51 comprises a metal. The metal unit 51b of the metal pad 51 comprises, for example, copper (Cu). The metal unit 51b of the metal pad 51 is, for example, copper (Cu).

The barrier metal film 51a of the metal pad 51 comprises, for example, a metal or metal nitride. In some examples, barrier metal film 51a comprises at least one metal element selected from the group consisting of titanium (Ti), tantalum (Ta), manganese (Mn), and cobalt (Co). The barrier metal film 51a is, for example, a titanium film, a titanium nitride film, or a tantalum nitride film.

The metal pad 52 is provided in the second direction from the metal pad 51. The metal pad 52 is surrounded by the second interlayer insulating layer 59. The metal pad 52 is in contact with the second conductive layer 56. The metal pad 52 is electrically connected to the second conductive layer 56 and the third conductive layer 57.

As illustrated in FIGS. 17 and 18, the metal pad 52 includes a barrier metal film 52a and a metal unit 52b. The barrier metal film 52a is provided between the metal unit 52b and the second conductive layer 56 and between the metal unit 52b and the second interlayer insulating layer 59.

The metal pad 52 comprises a metal. The metal unit 52b of the metal pad 52 comprises, for example, copper (Cu). The metal unit 52b of the metal pad 52 is, for example, copper (Cu).

The barrier metal film 52a of the metal pad 52 comprises, for example, a metal or metal nitride. In some examples, barrier metal film 52a comprises at least one metal element selected from the group consisting of titanium (Ti), tantalum (Ta), manganese (Mn), and cobalt (Co). The barrier metal film 52a is, for example, a titanium film, a titanium nitride film, or a tantalum nitride film.

The metal pad 52 can be the same material as the metal pad 51.

The external connection electrode pad layer 58 is provided on the front surface of the second memory chip 402. The external connection electrode pad layer 58 is provided for electrically connecting the second memory chip 402 and the outside. The external connection electrode pad layer 58 is connected, for example, to the first memory cell array 40 of the first memory chip 401 or a source or a drain of the transistor TR of the controller chip 403 via the wiring chip 102.

From the external connection electrode pad layer 58, a source voltage is applied, for example, to the first source semiconductor layer 46 and the second source semiconductor layer 55.

The external connection electrode pad layer 58 is a conductor material. The external connection electrode pad layer 58 comprises, for example, a metal. The external connection electrode pad layer 58 comprises, for example, aluminum (Al).

The second interlayer insulating layer 59 has a function of providing electrical insulation in the second memory chip 402. The second interlayer insulating layer 59 is an insulator material. The second interlayer insulating layer 59 comprises, for example, silicon oxide or silicon nitride.

The second interlayer insulating layer 59 is in contact with the first interlayer insulating layer 49. The interface between the second interlayer insulating layer 59 and the first interlayer insulating layer 49 is the first bonding interface BI1.

The controller chip 403 has a function of controlling memory operations of the first memory chip 401 and the second memory chip 402. The controller chip 403 is provided with an electronic circuit including the plurality of transistors TR. The transistor TR is, for example, a MOSFET obtained by forming channels on a silicon layer.

The metal pad 61 is surrounded by the third interlayer insulating layer 69. The metal pad 61 is electrically connected, for example, to the source or the drain of the transistor TR.

The metal pad 61 is in contact with the metal pad 43 of the first memory chip 401. The metal pad 61 is electrically connected to the metal pad 43.

The metal pad 62 is surrounded by the third interlayer insulating layer 69. The metal pad 62 is provided in the second direction from the metal pad 61. The metal pad 62 is electrically connected, for example, to the source or the drain of the transistor TR.

The metal pad 62 is in contact with the metal pad 44 of the first memory chip 401. The metal pad 62 is electrically connected to the metal pad 44.

As illustrated in FIG. 17, the first thickness (t1 in FIG. 17) of the metal pad 41 in the first direction is thinner than the second thickness (t2 in FIG. 17) of the metal pad 42 in the first direction. The first thickness t1 of the metal pad 41 in the first direction is, for example, equal to the distance from the first bonding interface BI1 to the first source semiconductor layer 46. The second thickness t2 of the metal pad 42 in the first direction is, for example, equal to the distance from the first bonding interface BI1 to the first conductive layer 48.

The second thickness t2 of the metal pad 42 is, for example, 1.5 times to 10 times of the first thickness t1 of the metal pad 41.

FIG. 18 is a plan view illustrating the front surface of the first bonding interface BI1 on the first memory chip 401 side. As illustrated in FIG. 18, the first area (S1 in FIG. 18) of the metal pad 41 on the first bonding interface BI1 is larger than the second area (S2 in FIG. 18) of the metal pad 42 on the first bonding interface BI1.

For example, when the metal pad 41 has a rectangular shape, the first area S1 of the metal pad 41 on the first bonding interface BI1 is a product of the width (w1a in FIG. 18) of the metal pad 41 in the second direction and the width (w1b in FIG. 18) in the third direction. In addition, for example, when the metal pad 42 has a rectangular shape, the second area S2 of the metal pad 42 on the first bonding interface BI1 is a product of the width (w2a in FIG. 18) of the metal pad 42 in the second direction and the width (w2b in FIG. 18) in the third direction.

The width w1a of the metal pad 41 in the second direction is, for example, larger than the width w2a of the metal pad 42 in the second direction. The width w1b of the metal pad 41 in the third direction is, for example, larger than the width w2b of the metal pad 42 in the third direction.

The volume of the metal pad 41 is, for example, 80% to 120% of the volume of the metal pad 42.

The volume of the metal pad 41 is, for example, the product of the first thickness t1 of the metal pad 41 and the first area S1 of the metal pad 41. The volume of the metal pad 42 is, for example, the product of the second thickness t2 of the metal pad 42 and the second area S2 of the metal pad 42.

For example, the product of the first thickness t1 of the metal pad 41 and the first area S1 of the metal pad 11 is 80% to 120% of the product of the second thickness t2 of the metal pad 42 in and the second area S2 of the metal pad 12.

In the nonvolatile semiconductor memory 400 according to the fourth embodiment, as illustrated in FIG. 18, the first area S1 of the metal pad 41 on the first bonding interface BI1 is larger than the second area S2 of the metal pad 42 on the first bonding interface BI1. Therefore, the amount of expansion of the metal pad 41 in the heat treatment increases and becomes close to the amount of expansion of the metal pad 42 in the heat treatment. Therefore, the occurrence of a bonding defect between the metal pad 41 and the metal pad 51 is reduced. Accordingly, the bonding characteristics between the first memory chip 401 and the second memory chip 402 are improved.

In view of preventing the occurrence of a bonding defect between the metal pad 41 and the metal pad 51 by causing the amount of expansion of the metal pad 41 and the metal pad 42 in the heat treatment to be close to each other, the volume of the metal pad 41 is preferably 80% to 120% of the volume of the metal pad 42 and is more preferably 90% to 110%.

The product of the first thickness t1 and the first area S1 of the metal pad 41 is preferably 80% to 120% of the product of the second thickness t2 and the second area S2 of the metal pad 42 and is more preferably 90% to 110%.

In view of preventing the occurrence of a bonding defect between the metal pad 41 and the metal pad 51, the product of the first thickness t1 and the first area S1 of the metal pad 41 is preferably larger than the product of the second thickness t2 and the second area S2 of the metal pad 42.

With the above, according to the fourth embodiment, it is possible to provide a semiconductor storage device in which bonding defects of the metal pads is reduced, and the bonding characteristics are improved.

In the first to fourth embodiments, a bonding interface is referenced. In an actual, final product, such as a logic IC or a nonvolatile semiconductor memory, the position of the bonding interface may not be clearly distinct upon examination. However, the position of the bonding interface in such cases may be determined by the positional deviation between the metal pads.

In the first to third embodiments, the semiconductor device is a logic IC, but the semiconductor device is not limited to being a logic IC.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a first chip that includes a first electrode and a second electrode; and
a second chip that includes a third electrode and a fourth electrode, the second chip being bonded to the first chip with the third electrode in contact with the first electrode and the fourth electrode in contact with the second electrode, wherein
a first thickness of the first electrode in a first direction perpendicular to a bonding interface between the first chip and the second chip is less than a second thickness of the second electrode in the first direction, and
a first area of the first electrode at the bonding interface is greater than a second area of the second electrode at the bonding interface.

2. The semiconductor device according to claim 1, wherein the product of the first thickness and the first area is 80% to 120% of the product of the second thickness and the second area.

3. The semiconductor device according to claim 1, wherein the product of the first thickness and the first area is greater than the product of the second thickness and the second area.

4. The semiconductor device according to claim 1, wherein the second thickness is 1.5 times to 10 times greater than the first thickness.

5. The semiconductor device according to claim 1, wherein the second chip further includes:
a fifth electrode that is in contact with the first electrode.

6. The semiconductor device according to claim 1, wherein the first chip further includes:
a first conductive layer in contact with the first electrode, and
a second conductive layer in contact with the second electrode.

7. The semiconductor device according to claim 1, wherein
the first chip further includes a fifth electrode,
the second chip further includes a sixth electrode in contact with the fifth electrode,
the second thickness is less than a third thickness of the fifth electrode in the first direction, and
the second area is greater than a third area of the fifth electrode at the bonding interface.

8. The semiconductor device according to claim 1, wherein the first electrode, the second electrode, the third electrode, and the fourth electrode each comprise copper.

9. A semiconductor storage device, comprising:
a first chip that includes:
a first memory cell array including:
a plurality of first gate electrode layers stacked in a first direction,
a first semiconductor layer extending in the first direction, and
a first charge storage layer between the first semiconductor layer and each first gate electrode layer,
a second semiconductor layer in the first direction from the first memory cell array and in contact with the first semiconductor layer,
a first conductive layer in a second direction perpendicular to the first direction from the first memory cell array and extending in the first direction,
a first electrode in contact with the second semiconductor layer, and
a second electrode in contact with the first conductive layer; and
a second chip bonded to the first chip, the second chip including:
a third electrode in contact with the first electrode, and
a fourth electrode in contact with the second electrode, wherein
a first thickness of the first electrode in the first direction is less than a second thickness of the second electrode in the first direction, and
a first area of the first electrode at a bonding interface between the first chip and the second chip is greater than a second area of the second electrode at the bonding interface.

10. The semiconductor storage device according to claim 9, wherein the second chip further includes:
a second memory cell array that includes:
a plurality of second gate electrode layers stacked in the first direction,
a third semiconductor layer extending in the first direction, and
a second charge storage layer between the third semiconductor layer and each second gate electrode layer.

11. The semiconductor storage device according to claim 10, wherein the third electrode is between the second memory cell array and the bonding interface.

12. The semiconductor storage device according to claim 11, wherein the second chip further includes:
a fourth semiconductor layer in the first direction from the second memory cell array that is in contact with the third semiconductor layer and electrically connected to the second semiconductor layer.

13. The semiconductor storage device according to claim 12, wherein the second chip further includes:
a second conductive layer between the third electrode and the second memory cell array, the second conductive layer being in contact with the third electrode and the fourth electrode.

14. The semiconductor storage device according to claim 13, wherein the second chip further includes:
a third conductive layer in the second direction from the second memory cell array, the third conductive layer extending in the first direction and electrically connected to the second conductive layer and the fourth semiconductor layer.

15. The semiconductor storage device according to claim 10, further comprising:
a third chip that includes a transistor and a fifth electrode and is bonded to the first chip, wherein
the first chip further includes a sixth electrode that is in contact with the fifth electrode.

16. The semiconductor storage device according to claim 9, wherein the product of the first thickness and the first area is 80% to 120% of the product of the second thickness and the second area.

17. The semiconductor storage device according to claim 9, wherein the product of the first thickness and the first area is greater than the product of the second thickness and the second area.

18. The semiconductor storage device according to claim 9, wherein the second thickness is 1.5 times to 10 times greater than the first thickness.

19. The semiconductor storage device according to claim 9, wherein the first electrode, the second electrode, the third electrode, and the fourth electrode each comprise copper.

20. The semiconductor storage device according to claim 19, wherein the product of the first thickness and the first area is 80% to 120% of the product of the second thickness and the second area.
